(19) United States
(12) Patent Application Publication
(10) Pub. No.: US 2026/0262527 A1
(43) Pub. Date: Sep. 3, 2026

(54) COMBINED VIA AND SOLDER BUMP FOR THREE-DIMENSIONAL INTEGRATION OF AN INFRARED DETECTOR

(71) Applicant: SEMICONDUCTOR COMPONENTS INDUSTRIES, LLC, Scottsdale, AZ (US)

(72) Inventors: Jeffrey Peter GAMBINO, Gresham, OR (US); James Joseph STEFFES, Poughkeepsie, NY (US); Christopher Lee TESSLER, Poughquag, NY (US); Gabrielle ROBERT, Fishkill, NY (US)

(73) Assignee: SEMICONDUCTOR COMPONENTS INDUSTRIES, LLC, Scottsdale, AZ (US)

(21) Appl. No.: 19/067,212

(22) Filed: Feb. 28, 2025

(51) Int. Cl. H01L 23/00; H01L 25/16; H10F 39/18; H10F 39/95; H10F 77/123

(52) U.S. Cl. CPC H10W 72/072; H10W 90/00; H10F 39/184; H10F 39/95; H10F 77/1237; H10W 72/01235; H10W 72/01255; H10W 72/221; H10W 72/222; H10W 72/252; H10W 80/312; H10W 80/327; H10W 90/722; H10W 90/792

(57) ABSTRACT

An infrared detector may include pixels on a compound-semiconductor substrate and the transistors for each pixel on a separate, silicon substrate. Communication between the substrates in this device may require a large number of connections at a very small scale. An inter-substrate connector is disclosed which can accommodate the very small scale. Each inter-substrate connector may include a combination of a via portion and a solder-bump portion (i.e., via bump). The via portion and the solder-bump portion may be produced by a plate-through-resist (PTR) process in which the portions, and at least one layer of solder, are deposited through openings etched in a photo resistive layer on the silicon substrate. The PTR process may be more efficient than other fabrication processes because it only requires one plating setup and no chemical metal planarization (CMP).

### FIELD OF THE DISCLOSURE

The present disclosure relates to back-end semiconductor processing and more specifically, to three-dimensional (3D) integration for a detector.

### BACKGROUND

3D integration may facilitate smaller electronic devices, which can lead to higher sensitivity and faster response times due to minimized signal loss. What is more, the low signal losses can reduce the power consumed by these devices. 3D integration can include vertically stacking integrated circuits (i.e., dies) to form a stack. When the layers in the stack are the same size and material, the electrical and mechanical connection can be carried out using wafer-to-wafer bonding (e.g., hybrid bonds). In other cases, the electrical and mechanical connection may be carried out using solder bumps. Interlayer connections via solder bumps may be more limited with respect to the density of the connections at the layer interface than wafer-to-wafer bonding.

### SUMMARY

The present disclosure describes an interlayer connector, and a fabrication method thereof, which can help increase the resolution and sensitivity of a detector which includes dissimilar layer sizes and materials.

In some aspects, the techniques described herein relate to a detector including: a sensor-die; and a pixel-device wafer coupled to the sensor-die using a plurality of via-bumps, wherein the plurality of via-bumps is produced using a process that includes: etching a plurality of nano-vias in a top surface of the pixel-device wafer; applying a resist layer to the top surface of the pixel-device wafer, the resist layer having a plurality of openings aligned with the plurality of nano-vias; plating multiple metals through the plurality of openings in the resist layer to form the plurality of via-bumps; and removing the resist layer.

In some aspects, the techniques described herein relate to a method, including: bonding a pixel-device wafer to an ASIC wafer to form a hybrid-ROIC wafer; etching a plurality of nano-vias into a top surface of the pixel-device wafer; producing a plurality of via-bumps at the plurality of nano-vias on the top surface of the pixel-device wafer using a process including: applying a resist layer to the top surface, the resist layer having openings aligned with the plurality of nano-vias; and plating multiple metals through the openings in the resist layer to form the plurality of via-bumps, the plurality of via-bumps (e.g., each via-bump) including a nano-via portion and a bump portion; and attaching a sensor-die to the plurality of via-bumps on the top surface of the hybrid-ROIC wafer.

In some aspects, the techniques described herein relate to a method for producing a via-bump, including: etching a nano-via into a top surface of a pixel-device wafer; applying a resist layer to the top surface, the resist layer having an opening aligned with the nano-via; plating multiple metals through the opening in the resist layer to create a nano-via portion and a bump portion of the via-bump; and removing the resist layer.

In some aspects, the techniques described herein relate to an infrared detector including: a pixel-device wafer bonded to an ASIC wafer to form a hybrid-ROIC wafer; and a sensor-die attached to via-bumps of a top surface of the hybrid-ROIC wafer, the via-bumps being spaced apart by a pitch of pixels on the sensor-die that is between 1 micrometer and 10 micrometers, and each via bump including: a nano-via portion that is copper; and a bump portion that includes a metal layer of copper adjacent to the nano-via portion and at least one layer of solder covering the metal layer of copper.

The foregoing illustrative summary, as well as other exemplary objectives and/or advantages of the disclosure, and the manner in which the same are accomplished, are further explained within the following detailed description and its accompanying drawings.

### BRIEF DESCRIPTION OF THE DRAWINGS

FIG. 1 is a side-view of a detector according to a possible implementation of the present disclosure.

FIG. 2 is a detailed side-view of a hybrid ROIC according to a possible implementation of the present disclosure.

FIG. 3A is a side view of a via-bump according to a first possible implementation of the present disclosure.

FIG. 3B is a side view of a via-bump according to a second possible implementation of the present disclosure.

FIG. 4 is a flowchart of a method for producing a via-bump according to a possible implementation of the present disclosure.

FIG. 5 are side-views of a via-bump at different steps of plate-through-resist (PTR) process according to a possible implementation of the present disclosure.

FIG. 6 is a flowchart of a method for fabricating a detector according to a possible implementation of the present disclosure.

FIG. 7 is an IR detector according to a possible implementation of the present disclosure.

The components in the drawings are not necessarily to scale relative to each other. Like reference numerals designate corresponding parts throughout the several views.

### DETAILED DESCRIPTION

For increased sensitivity in an infrared (IR) region of the electromagnetic spectrum (e.g., 1000 nm<λ<2000 nm), pixels of an IR detector may be fabricated on a compound-semiconductor layer, such as mercury cadmium telluride (i.e., HgCdTe). It may be more convenient to fabricate the devices (e.g., transistors) associated with the pixels on a separate silicon (Si) layer. Some technical problems with this approach are (i) wafer-to-wafer bonding may not be possible between the layers of different sizes and materials and (ii) connecting the pixels to their corresponding devices using conventional solder bumps may not be possible at a small pixel pitch.

An IR detector is disclosed that solves these technical problems using combined vias and solder bumps (i.e., via-bumps) for the connections between layers. The via-bumps can be arranged in a high-density pattern with a small connector pitch, which can be equal to the pixel pitch (e.g., 0.1 μm<pixel pitch<10 μm), and can further provide high electrical isolation between the pixels. A method for fabricating via-bumps is disclosed that can provide the accuracy necessary for high-density patterns, while at the same time only requiring a one-step process for metallization for the via and the solder bump, which is more efficient and accurate than using separate metallization processes for each. The IR detector implementation is described here in detail, but the disclosed techniques can be used in other devices that require a high-density of connections between wafers.

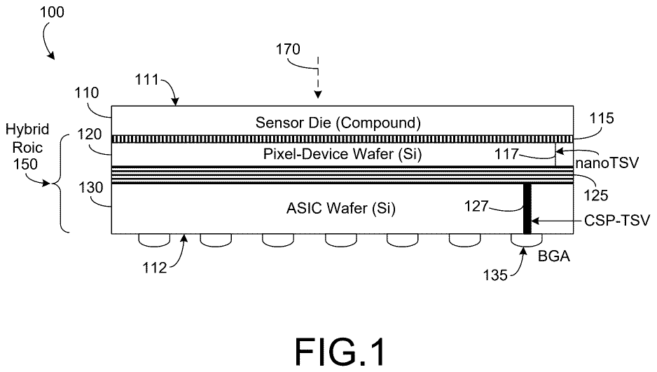

FIG. 1 is a side-view of a detector according to a possible implementation of the present disclosure. The detector 100 (e.g., IR detector, IR image sensor) includes integrated circuits, which are electrically and mechanically coupled to each other to form a stack. The frames of reference used to describe the drawings shown herein will refer to relative positions (e.g., top, bottom, over, under, etc.) and relative directions (e.g., vertical, horizontal, etc.) as they are shown on the page. For example, the detector may include a top surface 111 that faces incoming light 170 and a bottom surface 112 that can be connected to a printed circuit board (not shown). Accordingly, the stack may be referred to as a vertical stack. Each layer in the vertical stack may include a respective top surface, which is closer to the top surface 111 of the vertical stack and a respective bottom surface, which is closer to the bottom surface 112 of the vertical stack. This chosen frame of reference is not intended to be limiting because other frames of reference may be used to describe the same device.

As shown in FIG. 1, the detector 100 includes a sensor layer (i.e., sensor-die 110) configured to receive the light (e.g., infrared light) at the top surface 111. The sensor-die 110 may include a plurality of photodiodes (i.e., pixels), each configured to generate an electrical signal (e.g., current) in proportion to an amount of light received at the pixel. The pixels may be arranged in a two-dimensional array so that they can be addressed by row and column. The sensor-die 110 may further include row and column conductors (i.e., metal layer) configured to connect the pixels to pads on a bottom surface of the sensor-die 110.

The sensor-die 110 may be fabricated using a compound semiconductor (i.e., compound) substrate. The compound substrate may be chosen based on its sensitivity to the incoming light 170. The pixels fabricated from the compound semiconductor may have a higher quantum efficiency than pixels fabricated from silicon (Si) for infrared wavelengths. In a possible implementation, the sensor-die 110 may be mercury cadmium telluride (HgCdTe), which has a higher quantum efficiency than silicon (Si) for wavelengths (λ) between 1 micrometer and 10 micrometers (i.e., 1 μm≤λ≤10 μm).

The detector 100 further includes a pixel-device wafer 120. The pixel-device wafer 120 may include transistors (e.g., field effect transistors) for each pixel. The transistors are used to control (e.g., address) the pixels in the sensor-die 110. For example, the pixel-device wafer 120 may include transistors configured to couple a pixel to a respective row conductor and a respective column conductor for readout. In a possible implementation, the pixel-device wafer 120 is fabricated using a silicon substrate because there may be few (e.g., no) advantages in using the compound-semiconductor substrate for the pixel transistors, while there may be multiple disadvantages in doing so, including cost and complexity. Conversely, there may be many advantages, such as cost and ease, in using a silicon substrate for the pixel transistors.

The detector 100 further includes an application specific integrated circuit wafer (ASIC wafer 130). The ASIC wafer 130 may include the logic and circuitry (e.g., digital logic) to control the transistors of the pixel-device wafer 120 to address (e.g., read) the pixels of the sensor-die 110. In a possible implementation, the ASIC wafer 130 is fabricated using a silicon substrate. Besides being the same material, the pixel-device wafer 120 and the ASIC wafer 130 may be the same size (horizontally).

The pixel-device wafer 120 and the ASIC wafer 130 may be connected mechanically and electrically at a hybrid-bond interface 125. The hybrid-bond interface 125 may be a direct wafer-to-wafer connection that includes dielectric bonds and metal connections. Each metal connection may be formed (e.g., using heat and/or pressure) between a metal pad at a bottom surface of the pixel-device wafer 120 and a metal pad at a top surface of the ASIC wafer 130. The density of the metal bonds may be high because the metal connections may have a very small area (e.g., <1 μm²). The hybrid-bond interface 125 may be suitable for this connection because the pixel-device wafer 120 and the ASIC wafer 130 are the same material.

The pixel-device wafer 120 and the ASIC wafer 130 may be referred to in combination as the hybrid readout integrated circuit (i.e., hybrid ROIC 150). The hybrid ROIC is configured to collect, amplify and process (e.g., digitize) signals generated by the pixels. The hybrid ROIC 150 can reduce the size (e.g., footprint) of the detector 100 compared to other designs that do not separate the pixel-device wafer 120 and the sensor-die 110. The hybrid-bond interface 125 of the hybrid ROIC 150 can reduce the resistance between pixel transistors and digital logic devices, which can improve performance (e.g. increase speed, reduce power consumption) of the detector 100 compared to other designs that do not separate the pixel-device wafer 120 and the sensor-die 110. The present disclosure describes an inter-layer connector to facilitate the hybrid ROIC 150.

The hybrid-bond interface 125 used in the hybrid ROIC 150 may not be practical, or possible, for an interface 115 between the sensor-die 110 and the pixel-device wafer 120 because of differences in the substrates (e.g., substrate material, substrate size, etc.). Further, the density of the connections required between the sensor-die 110 and the pixel-device wafer 120 may correspond to the array of pixels (e.g., resolution, size). For example, a spacing (i.e., pitch) between connections may be between 1 micrometer and 10 micrometers, which is much smaller than can be proved by an inter-layer connector that includes a (conventional) BGA solder bump 135 and a (conventional) chip-scale package (CSP) through silicon vias (CSP-TSV 127). The CSP vias may be spaced apart by a pitch that is greater than 100 micrometers.

The present disclosure describes an inter-layer connector that is (i) suitable for a connection density required for a high-resolution (e.g., 1028×1028) pixel array and that is (ii) suitable for connecting layers of different materials and sizes (e.g., horizontal widths). The disclosed interlayer connector includes a metallization structure that combines a nanometer sized (e.g., <1 micrometer (μm)) through-silicon-via (i.e., nano-via 117) and a nanometer sized solder bump (i.e., nano-bump). For example, each nano-via 117 has a diameter that is less than 1 micrometer, and the nano-vias are spaced apart by a pitch that is between 1 micrometer and 10 micrometers. The nano-bumps may be connected to the pads on the bottom of the sensor-die 110 at the interface 115 between the sensor-die 110 and the pixel-device wafer 120. The nano-via 117 may have a length (e.g., 1 μm≤L≤3 μm) and a diameter (e.g., 0.1 μm≤D≤5 μm) that is smaller than the CSP-TSV 127. The shorter length of the nano-via 117 may correspond to a connection having a lower resistance than a connection using a CSP-TSV 127. As will be shown, a material (e.g., copper) filling the nano-via 117 may also provide a connection having a lower resistance and higher thermal conductivity than a material (e.g., solder) lining a CSP-TSV 127. The lower resistance may correspond to a low electrical loss (i.e., lower power consumption) and a fast-switching speed for the detector 100.

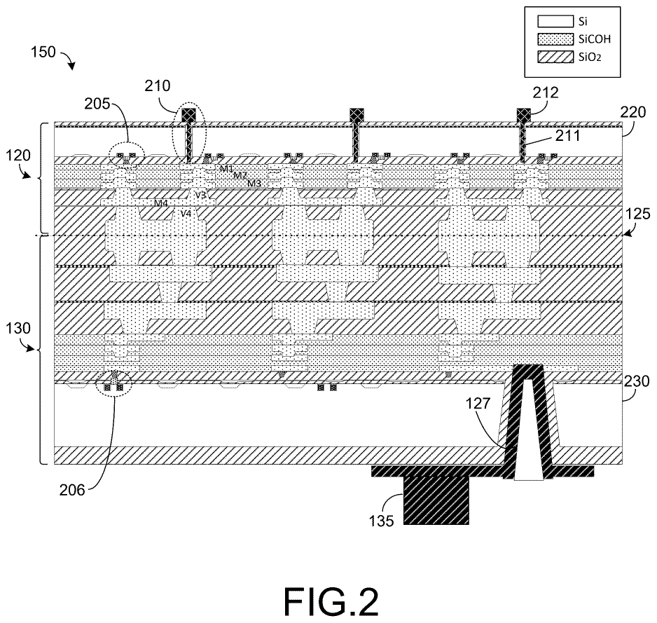

FIG. 2 is a detailed side-view of a hybrid ROIC according to a possible implementation of the present disclosure. As shown, the hybrid ROIC 150 includes the pixel-device wafer 120 connected to the ASIC wafer 130 by the hybrid-bond interface 125. The pixel-device wafer 120 may include a first silicon substrate 220 that is thinner than a second silicon substrate 230 of the ASIC wafer 130. In a possible implementation, the first silicon substrate 220 of the pixel-device wafer 120 is 3 micrometers thick while the second silicon substrate 230 of the ASIC wafer 130 is 100 micrometers thick.

The pixel-device wafer 120 may include transistors 205 fabricated at a bottom surface of the pixel-device wafer 120. The transistors 205 may be coupled through metal layers (M1- M4) and vias (V3, V4) to the hybrid-bond interface 125. In a possible implementation, the metal layers and vias may be fabricated in a plurality of insulating layers (e.g., SiCOH layers, SiO₂ layers).

The ASIC wafer 130 may include devices 206 (e.g., transistors, digital logic devices, etc.) fabricated at a top surface of the ASIC wafer 130. The devices 206 may be coupled through metal layers (M1-M4) and vias to the hybrid-bond interface 125. In a possible implementation, the metal layers and vias may be fabricated in a plurality of insulating layers (e.g., SiCOH, SiO₂). The devices 206 may be coupled to a BGA solder bump 135 by a CSP-TSV 127 in the second silicon substrate 230. In a possible implementation, the BGA solder bump 135 is a solder material, such as tin (Sn), and the CSP-TSV 127 is plated with a layer of metal, such as copper (Cu) or aluminum (Al). The pixel-device wafer 120 and the ASIC wafer 130 can be bonded at the hybrid-bond interface 125 to create the hybrid ROIC 150.

Nanometer-scaled vias (i.e., nano-vias) may be etched through the first silicon substrate 220 and plated using a plate-through-resist process to produce a via-bumps 210 that each includes a nano-via portion 211 and a bump portion 212. A sensor-die may (not shown) be connected mechanically and electrically (e.g., soldered) to the top surface of the hybrid ROIC 150 by the via-bumps 210.

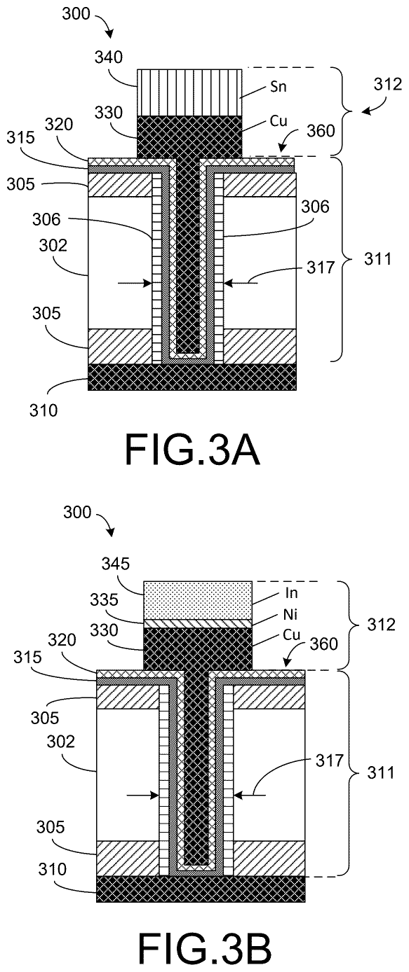

FIG. 3A is a side view of a via-bump according to a first possible implementation of the present disclosure. The via-bump 300 is configured to connect a metal layer 310 (e.g., M1) of a first integrated circuit (e.g., pixel-device wafer 120) to a second integrated circuit (e.g., sensor-die 110). As shown, an insulating layer 305, such as SiO2, may cover a bottom surface (and a top surface) of a silicon substrate 302 to prevent leakage currents. A nano-via 317, which can be formed by an etching process, penetrates the silicon substrate 302 and the insulating layer 305 (which can include a top insulating layer and a bottom insulating layer) and is configured to accept layers of material to insulate and help the plating of the via-bump material.

The layers may include an insulating spacer 306 deposited (e.g., using a spacer-etch process) on the sidewalls of the nano-via 317. The insulating spacer 306 may be an oxide material, such as silicon oxide (SiO₂) and may perform the same function as the insulating layer 305 at the top/bottom of the silicon substrate 302.

The layers may further include a barrier-metal layer 315 deposited on the top surface of the wafer and in the nano-via, covering the insulating spacer 306. The barrier-metal layer 315 may isolate the via-bump 300 from the silicon substrate 302. The isolation can prevent leakage current between via-bumps and can prevent migration of metal into the silicon.

The layers may further include a barrier-metal layer 315. The barrier-metal layer 315 may be a refractory metal, such as titanium (Ti), tungsten (W), tantalum (Ta), tantalum nitride (TaN), titanium nitride (TiN), or a titanium-tungsten alloy. The barrier-metal layer 315 is deposited (e.g., using a sputter-deposition process) to prevent the metal layer 310 (e.g., aluminum or copper) from reacting with the metal of the via-bump 300 (e.g., copper). The barrier-metal layer 315 may be further configured as a seed layer for a subsequent copper plating process to help adhesion of the copper to the insulating layer 305 (e.g., SiO₂).

The layers further include copper-seed layer 320. The copper-seed layer 320 is copper that is deposited (e.g., using a sputter-deposition process) to improve the adhesion and density of the metal plating used to create the via-bump. The copper-seed layer 320 can be deposited in the nano-via 317 and on a top surface 360 of the integrated circuit to serve as an under-bump metallization.

After the nano-via 317 is formed (e.g. etched) and the layers are deposited, a via-bump may be produced using a plate-through-resist process. The plate-through-resist process allows the use of the same metal (e.g., copper) for a copper bump 330 and the under-bump metallization. The plate-through-resist process also allows for a nano-via portion 311 and the bump portion 312 to be plated in one process. In other words, one plating setup may be used to create the barrier metallization, the seed metallization, the nano-via 317, and the copper bump 330.

The plate-through-resist process may include plating a solder layer or layers onto the copper bump 330. As shown in FIG. 3A, a solder layer 340 may be plated onto the copper bump 330 to form a solder bond with a connector (e.g., pad) on a separate substrate (not shown). As will be shown, plating the solder layer 340 onto the copper bump 330 does not require any intervening chemical mechanical planarization step. As shown in the first implementation of FIG. 3A the bump portion 312 includes two metal layers: copper (Cu) (i.e., the bump) and tin (Sn) (i.e., the solder plating). In other implementations, the bump portion 312 may include more than two metal layers.

FIG. 3B is a side view of a via-bump according to a second possible implementation of the present disclosure. As shown in the second implementation, the metal layers of the bump portion 312 include copper (Cu), nickel (Ni), and indium (In). The indium layer 345, which is the solder layer, may face the sensor-die during attachment. The nickel layer 335 is plated between the copper bump 330 and the indium layer 345 to prevent the indium and the copper from reacting.

The solder layers used (e.g., tin, indium) may have a relatively low melting point to prevent the attachment of the sensor-die to the via-bumps on the top surface of the hybrid-ROIC wafer from affecting the hybrid bond, which may have a relatively high melting point.

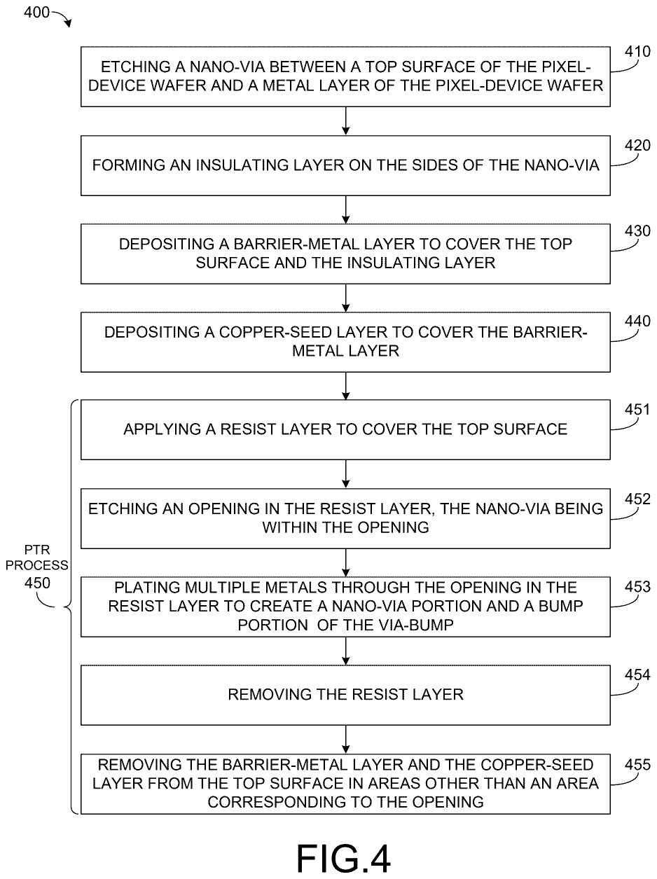

FIG. 4 is a flowchart of a method for producing a via-bump according to a possible implementation of the present disclosure. The method 400 includes etching 410 a nano-via into a top surface of a wafer. For example, the nano-via may be etched so that an opening is formed, through a substrate (e.g., silicon substrate), between a top surface of a pixel-device wafer and a metal layer of the pixel-device wafer. The method 400 further includes forming 420 (e.g., depositing) an insulating layer on the side walls (i.e., vertical sides, sides) of the nano-via. The method 400 further includes depositing 430 (e.g., sputtering) a barrier-metal layer to cover the top surface and the insulating layer in the nano-via. The method 400 further includes depositing 440 a copper-seed layer to cover the barrier-metal layer. The method 400 further includes plating according to a plate-through-resist process (i.e., PTR process 450) in order to create a via-bump including a nano-via portion and a bump portion in a single plating process that does not include a chemical mechanical planarization (CMP) step.

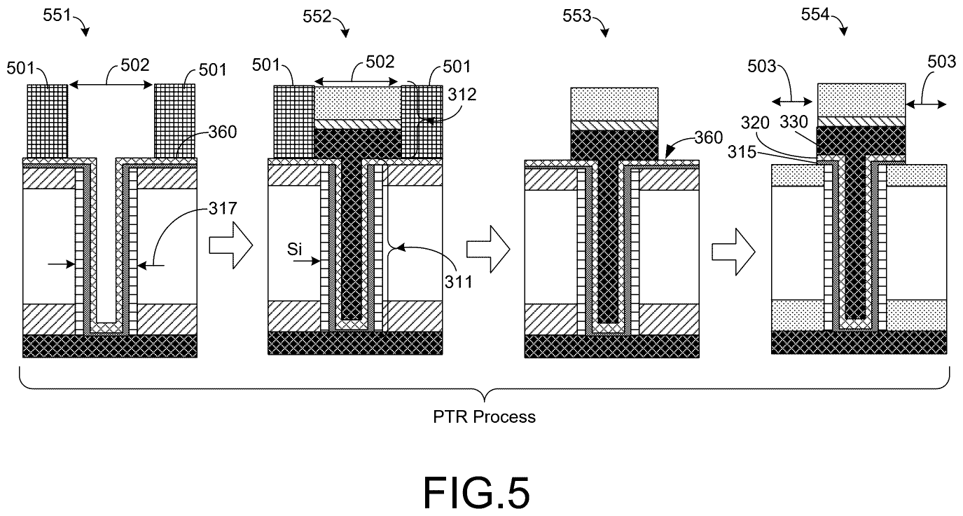

The PTR process 450 will be described in conjunction with FIG. 5, which includes side-views of a via-bump after different steps of the PTR process 450 according to a possible implementation of the present disclosure.

The PTR process 450 includes a first PTR step of applying 451 a resist layer 501 (e.g., photo-resist layer) to the top surface and etching 452 an opening in the resist layer, where the opening includes the nano-via. FIG. 5 illustrates the via-bump after the first PTR step 551 of applying the resist layer 501 on the top surface 360. The resist layer 501 includes an opening 502 that includes (e.g., is centered on) the nano-via 317.

The PTR process 450 further includes a second PTR step of plating 453 multiple metals through the opening 502 in the resist layer 501 to create the nano-via portion 311 and the bump portion 312 of the via-bump. FIG. 5 illustrates the via-bump after the second PTR step 552 of plating (e.g., electroplating) multiple metals (e.g., copper, solder) through the opening 502 in the resist layer 501 to create the nano-via portion 311 and the bump portion 312 of the via-bump.

The PTR process 450 further includes a third step of removing 454 (e.g., stripping) the resist layer 501 from the top surface 360. FIG. 5 illustrates the via-bump after the third PTR step 553 of removing the resist layer 501 from the top surface 360.

The PTR process 450 further includes a fourth step of removing 455 the barrier-metal layer 315 and the copper-seed layer 320 from the top surface 360. The layers may be removed in areas on the top surface 360 other than an area corresponding to the opening. In other words, the removal leaves the barrier-metal layer 315 and the copper-seed layer 320 under the copper bump 330 but otherwise removes it from the top surface 360. FIG. 5 illustrates the via-bump after the fourth PTR step 554 of removing the barrier-metal layer 315 and the copper-seed layer 320 from the top surface 360 in areas 503 other than the bump portion 312.

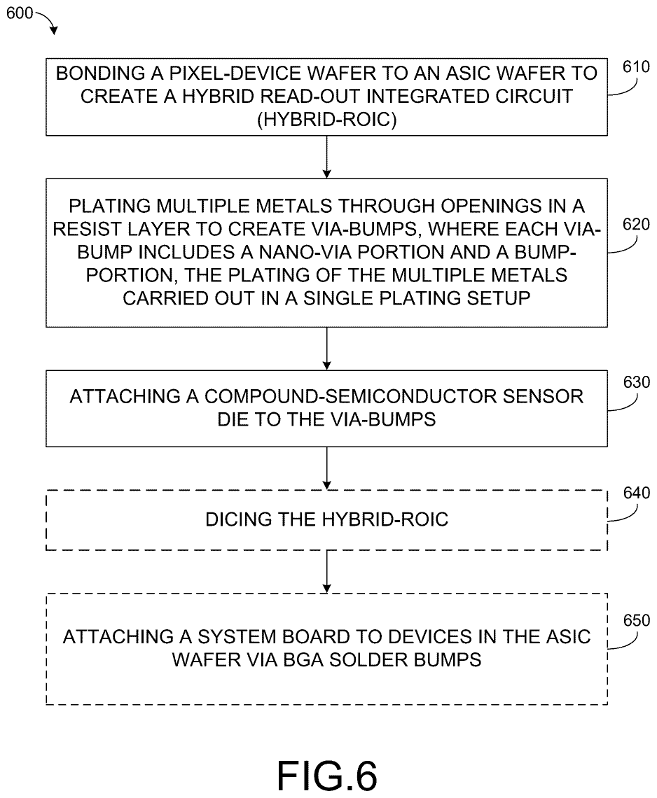

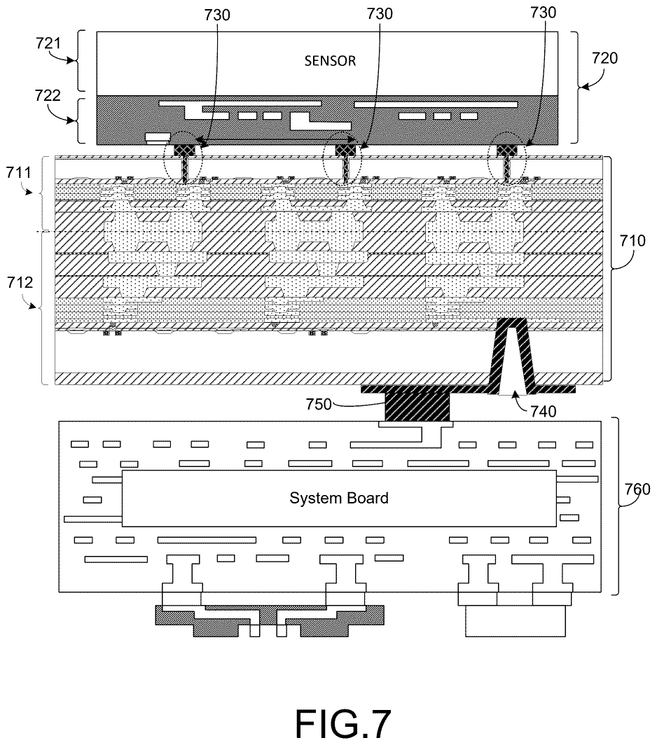

FIG. 6 is a flowchart of a method for fabricating a detector according to a possible implementation of the present disclosure. The method 600 will be discussed in conjunction with FIG. 7, which illustrates an IR detector according to a possible implementation of the present disclosure.

The method 600 further includes bonding 610 a pixel-device wafer 711 to an ASIC wafer 712 to create a hybrid-ROIC 710. The method 600 further includes plating 620 multiple metals through openings in a resist layer, which are aligned with the nano-vias, to create via-bumps 730. Each via-bump includes a nano-via portion that couples a bump-portion to a device (e.g., n-type field effect transistor (nFET)) via a metal layer (e.g., M1) of the pixel-device wafer 711. The via-bumps 730 may be spaced very close (e.g., 2 micrometers).

The method 600 further includes attaching 630 (e.g., soldering) a sensor-die 720 to the via-bumps 730. The sensor-die 720 may be a compound-semiconductor material (e.g., HgCdTe). The sensor-die 720 may include multiple layers and may have a different dimension than the pixel-device wafer 711. For example, the sensor-die 720 may include a sensor layer 721 that includes photodiodes, which can be arranged in rows and columns to create a 2D array of pixels. The sensor-die 720 may further include a metal layer 722 that includes row and column conductors configured to couple to the pixels to corresponding devices on the pixel-device wafer 711.

The method 600 can further include dicing 640 the hybrid-ROIC 710 and attaching 650 a system board 760 to the hybrid-ROIC 710. The system board 760 may be a low-temperature co-fired ceramic (LTCC). The attachment to the system board 760 may be achieved using conventional interlayer connectors. Each conventional interlayer connector can include a ball grid array (BGA) solder bump 750 (e.g., ball-grid-array solder bump, tin BGA solder bump) and a chip-scale package (CSP) through-silicon via (TSV) 740 (e.g., chip-scale-package via). The BGA solder bump 750 may be much larger (e.g., >100 times larger) than a bump portion 312 of a via-bump and may be tin (Sn) rather than copper. The CSP-TSV 740 may be a through-hole that is plated on its sides with solder.

The nano-via portion 311 may be filled with copper to compensate for some performance degradation that could result by using solder (e.g., Sn) in a via-portion with a small (e.g., <5 micrometer) diameter. First, copper has very low electromigration compared to solder. For example, an electromigration lifetime of copper may be 100 times larger than the electromigration lifetime of solder. Second, copper may have lower resistance than solder. For example, the resistivity of copper may be 10 times lower than solder.

In the specification and/or figures, typical embodiments have been disclosed. The present disclosure is not limited to such exemplary embodiments. The use of the term “and/or” includes any and all combinations of one or more of the associated listed items. The figures are schematic representations and so are not necessarily drawn to scale. Unless otherwise noted, specific terms have been used in a generic and descriptive sense and not for purposes of limitation.

Unless defined otherwise, all technical and scientific terms used herein have the same meaning as commonly understood by one of ordinary skill in the art. Methods and materials similar or equivalent to those described herein can be used in the practice or testing of the present disclosure. As used in the specification, and in the appended claims, the singular forms “a,” “an,” “the” include plural referents unless the context clearly dictates otherwise. The term “comprising” and variations thereof as used herein is used synonymously with the term “including” and variations thereof and are open, non-limiting terms. The terms “optional” or “optionally” used herein mean that the subsequently described feature, event or circumstance may or may not occur, and that the description includes instances where said feature, event or circumstance occurs and instances where it does not. Ranges may be expressed herein as from “about” one particular value, and/or to “about” another particular value. When such a range is expressed, an aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

It will be understood that, in the foregoing description, when an element is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element, there are no intervening elements present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

1. A detector comprising:
a sensor-die; and
a pixel-device wafer coupled to the sensor-die using a plurality of via-bumps, wherein the plurality of via-bumps is produced using a process that includes:
etching a plurality of nano-vias in a top surface of the pixel-device wafer;
applying a resist layer to the top surface of the pixel-device wafer, the resist layer having a plurality of openings aligned with the plurality of nano-vias;
plating multiple metals through the plurality of openings in the resist layer to form the plurality of via-bumps; and
removing the resist layer.

2. The detector according to claim 1, wherein:
the sensor-die is a compound semiconductor; and
the pixel-device wafer is silicon (Si).

3. The detector according to claim 1, wherein:
the plurality of nano-vias each have a diameter that is less than 1 micrometer; and
the plurality of nano-vias are spaced apart by a pitch that is between 1 micrometer and 10 micrometers.

4. The detector according to claim 1, wherein plating the multiple metals through the plurality of openings in the resist layer creates a nano-via portion of a via-bump and a bump portion of the via-bump in a single plating process.

5. The detector according to claim 4, wherein the single plating process does not include a chemical mechanical planarization (CMP) step.

6. A method, comprising:
bonding a pixel-device wafer to an ASIC wafer to form a hybrid-ROIC wafer;
etching a plurality of nano-vias into a top surface of the pixel-device wafer;
producing a plurality of via-bumps at the plurality of nano-vias on the top surface of the pixel-device wafer using a process including:
applying a resist layer to the top surface, the resist layer having openings aligned with the plurality of nano-vias; and
plating multiple metals through the openings in the resist layer to form the plurality of via-bumps, the plurality of via-bumps including a nano-via portion and a bump portion; and
attaching a sensor-die to the plurality of via-bumps on the top surface of the hybrid-ROIC wafer.

7. The method according to claim 6, wherein:
the sensor-die is a compound semiconductor; and
the pixel-device wafer and the ASIC wafer are silicon (Si).

8. The method according to claim 7, wherein:
the compound semiconductor is mercury cadmium telluride (HgCdTe).

9. The method according to claim 6, wherein:
the pixel-device wafer includes transistors for controlling pixels of the sensor-die;
the ASIC wafer includes digital logic for controlling the transistors; and
the bonding of the pixel-device wafer to the ASIC wafer is a hybrid-bond.

10. The method according to claim 6, wherein:
the plurality of nano-vias have a diameter that is less than 1 micrometer; and
the plurality of nano-vias are spaced apart by a pitch that is between 1 micrometer and 10 micrometers.

11. The method according to claim 6, wherein plating the multiple metals through the openings in the resist layer creates the nano-via portion and the bump portion in a single plating process.

12. The method according to claim 11, wherein the single plating process does not include a chemical mechanical planarization (CMP) step.

13. The method according to claim 6, wherein:
the nano-via portion is copper; and
the bump portion includes metal layers of copper (Cu) and tin (Sn), the tin facing the sensor-die during the attaching.

14. The method according to claim 6, wherein:
the nano-via portion is copper; and
the bump portion includes metal layers of copper (Cu), nickel (Ni), and Indium (In), the indium facing the sensor-die during the attaching and the nickel being between the copper and the indium.

15. The method according to claim 6, further comprising:
producing chip-scale-package (CSP) vias in a bottom surface of the ASIC wafer, the CSP vias spaced apart by a pitch that is greater than 100 micrometers;
connecting ball-grid-array (BGA) solder bumps to the CSP vias; and
attaching a system board to the BGA solder bumps.

16. A method for producing a via-bump, comprising:
etching a nano-via into a top surface of a pixel-device wafer;
applying a resist layer to the top surface, the resist layer having an opening aligned with the nano-via;
plating multiple metals through the opening in the resist layer to create a nano-via portion and a bump portion of the via-bump; and
removing the resist layer.

17. The method for producing the via-bump according to claim 16, further comprising:
forming an insulating layer on sides of the nano-via after etching the nano-via;
sputtering a barrier-metal layer to cover the top surface and the insulating layer;
sputtering a copper-seed layer on the barrier-metal layer;
removing the resist layer after the plating; and
removing the barrier-metal layer and the copper-seed layer from the top surface in areas other than an area corresponding to the opening.

18. The method for producing the via-bump according to claim 16, wherein plating the multiple metals through the opening in the resist layer creates the nano-via portion and the bump portion in a single plating process.

19. The method for producing the via-bump according to claim 18, wherein the single plating process does not include a chemical mechanical planarization (CMP) step.

20. The method for producing the via-bump according to claim 16, wherein plating the multiple metals through the opening in the resist layer includes:
plating copper to form the nano-via portion; and
plating a layer of copper (Cu) and at least one laser of solder to form the bump portion.
